(19) United States
(12) Patent Application Publication
(10) Pub. No.: US 2025/0194302 A1
(43) Pub. Date: Jun. 12, 2025

(54) DISPLAY DEVICE

(71) Applicant: LG Display Co., Ltd., Seoul (KR)

(72) Inventor: Heumell BAEK, Paju-si (KR)

(21) Appl. No.: 18/768,857

(22) Filed: Jul. 10, 2024

(30) Foreign Application Priority Data
Dec. 6, 2023 (KR) 10-2023-0175964

(51) Int. Cl. H01L 33/20; H01L 25/16; H01L 33/40; H01L 33/62

(52) U.S. Cl. CPC H10H 20/819; H01L 25/167; H10H 20/835; H10H 20/857

(57) ABSTRACT

A display device includes a substrate and sub-pixels disposed on the substrate. The display device further includes an emitting area and a non-emitting area surrounding the emitting area as well as a first thin film transistor and a second thin film transistor disposed on the substrate in the non-emitting area, and a light emitting diode disposed on the substrate in the emitting area. The light emitting diode includes a first p-type electrode electrically connected to the first thin film transistor and a second p-type electrode electrically connected to the second thin film transistor.

### CROSS-REFERENCE TO RELATED APPLICATIONS

This application claims the benefit of the Republic of Korean Patent Application No. 10-2023-0175964 filed on Dec. 6, 2023, which is incorporated herein by reference as if fully set forth herein.

### BACKGROUND

### Technical Field

The present disclosure relates to a display device and more particularly, to a display device using a light emitting diode.

### Description of the Related Art

In addition to the display screen of a television or monitor, a display device is widely used as a notebook computer, a tablet computer, a smart phone, a portable display device, and a portable information device display screen. A liquid crystal display device and an organic light emitting display device display an image using a transistor as switching elements. Since the liquid crystal display device does not use its own light emitting method, the image is displayed using light irradiated from the backlight unit disposed under the liquid crystal display panel. Since such a liquid crystal display device has a backlight unit, there is a limitation in design, and luminance and response speed may be lowered. Since the organic light emitting display device includes an organic material, it is vulnerable to moisture, and reliability and lifespan may be deteriorated.

Recently, research and development of a double-sided light emitting display device have been conducted. However, since one pixel includes a plurality of light emitting devices, various limitations such as an increase in process difficulty have occurred.

As a result, it would be advantageous to have a display device that overcomes the above and other deficiencies and disadvantages with known display technology.

### BRIEF SUMMARY

The present disclosure is generally directed to a double-sided display device using or incorporating a light emitting diode that emits light to an upper direction and a lower direction.

In an embodiment, a display device may include a substrate on which a plurality of sub-pixels are disposed with each of the plurality of sub-pixels including an emitting area and a non-emitting area surrounding the emitting area. The display device may further include a first thin film transistor and a second thin film transistor disposed in the non-emitting area on the substrate, and a light emitting diode disposed in the emitting area on the substrate, wherein the light emitting diode includes a first p-type electrode electrically connected to the first thin film transistor and a second p-type electrode electrically connected to the second thin film transistor.

Additional embodiments and advantages of the techniques of the disclosure will be provided in the following description with reference to the accompanying drawings. Accordingly, the disclosure is not limited by the above summary.

### BRIEF DESCRIPTION OF THE SEVERAL VIEWS OF THE DRAWINGS

FIG. 1 is plan view of a display device according to an embodiment of the present disclosure.

FIGS. 2 and 3 are plan views of a pixel of the display device of FIG. 1.

FIG. 4 is a cross-sectional view of a subpixel of the pixel of FIG. 3 along line I-I′ in FIG. 3.

FIG. 5 is a cross-sectional view of a subpixel according to an embodiment of the present disclosure.

FIG. 6 is a cross-sectional view of a further subpixel of the pixel of FIG. 3 along line II-II′ in FIG. 3.

FIGS. 7A to 71 are cross-sectional views of steps in a manufacturing process for a display device according to one or more embodiments of the present disclosure.

FIG. 8 is a circuit diagram of a sub-pixel according to an embodiment of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the scope of the claims is not limited by the following disclosure.

A shape, a size, a ratio, an angle and a number disclosed in the drawings for describing embodiments of the present disclosure are merely an example and thus, the present disclosure is not limited to the illustrated details. Like reference numerals refer to like elements throughout the specification, unless otherwise indicated. In the following description, when the detailed description of the relevant known function or configuration is determined to unnecessarily obscure the important point of the present disclosure, the detailed description will be omitted. In a case where ‘comprise,’ ‘have’ and ‘include’ described in the present disclosure are used, another portion may be added unless ‘only-’ is used. The terms of a singular form may include plural forms unless referred to the contrary.

In construing an element, the element is construed as including an error band or ordinary error range although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Hereinafter, the preferred embodiment of the present disclosure will be described in detail with reference to the accompanying drawings.

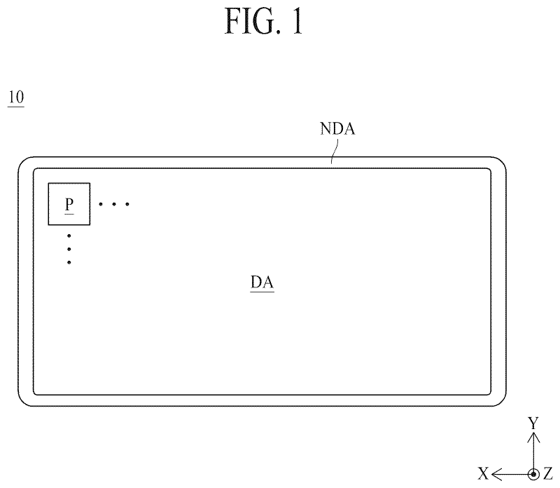

FIG. 1 is a plan view of a display device 10 according to an embodiment of the present disclosure.

Referring to FIG. 1, the display device 10 according to an embodiment of the present disclosure may include a display area DA and a non-display area NDA surrounding the display area DA. The display area DA is an area in which an image is displayed, and the non-display area NDA is an area in which an image is not displayed.

The display area DA may include a plurality of pixels P. The plurality of pixels P may be arranged in a matrix formed of a plurality of rows and columns. Also, the non-display area NDA may include a plurality of wirings, pads, driving circuits, etc., for driving a plurality of pixels P.

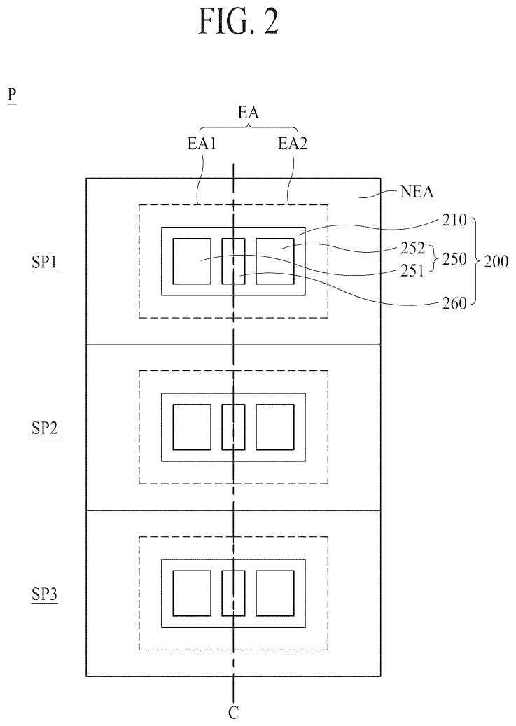

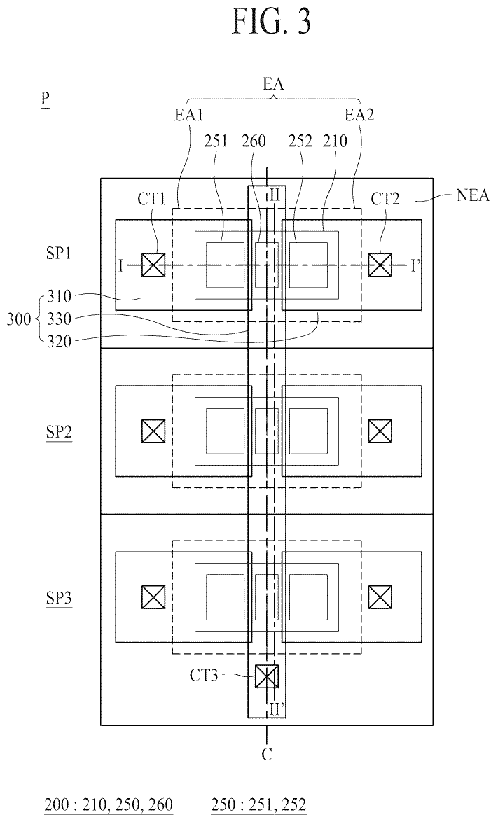

FIGS. 2 and 3 are plan views of one pixel P of the plurality of pixels P of the display device 10 according to an embodiment of the present disclosure. FIG. 3 illustrates a structure in which a connection electrode 300 and a contact hole CT are additionally formed in the pixel P shown in FIG. 2.

Referring to FIGS. 2 and 3, each of the plurality of pixels P may include first, second and third sub-pixels SP1, SP2 and SP3. The first, second and third subpixels SP1, SP2 and SP3 may emit different light from each other. For example, the first sub-pixel SP1 may emit red light, the second sub-pixel SP2 may emit green light, and the third sub-pixel SP3 may emit blue light, but is not limited thereto. Also, although FIG. 2 and FIG. 3 disclose that one-pixel P includes three sub-pixels SP1 to SP3, the present disclosure is not limited thereto, and one-pixel P may include more or less sub-pixels.

Each of the first, second and third sub-pixels SP1, SP2 and SP3 may include an emitting area EA and a non-emitting area NEA surrounding the emitting area EA. The emitting area EA is an area that emits light, and the non-light emitting area NEA is an area that does not emit light. In an embodiment, the emitting area EA may include a first emitting area EA1 and a second emitting area EA2. The first emitting area EA1 may emit light in a lower direction of the display device, and the second emitting area EA2 may emit light in an upper direction of the display device. For example, and referring back to FIG. 1, the first emitting area EA1 may emit light in a first direction into the page along the Z axis (i.e., a negative Z direction) and the second emitting area EA2 may emit light in a second direction out of the page along the Z axis (i.e, a positive Z direction) that is generally opposite to the first direction. Accordingly, the display device 10 including the first and second emitting areas EA1, EA2 is a double-sided display device configured to emit light in two different directions, such as away from a front and rear surface of the display device 10.

Returning to FIG. 2 and FIG. 3, the pixel P may include a center line C that is a vertical or horizontal axis (depending on the orientation of the display device 10) that extends through a center of the pixel P. In FIG. 2, the center line C is illustrated as a central vertical axis through each sub-pixel SP1, SP2, SP3. Thus, in an embodiment, the center line C extends through a center of the emitting area EA to divide the emitting area EA into the first emitting area EA1 on one side (i.e., a left side) of the center line C and the second emitting area EA2 on the other side (i.e., a right side) of the center line C. That is, the boundary between the first and second emitting areas EA1 and EA2 may be formed on the center line C of the sub-pixel SP with the emitting areas EA1, EA2 generally being on opposite sides of the center line C. Also, the sizes of the first and second emitting areas EA1 and EA2 may preferably be the same with the emitting area EA centered on the center line C, although the same is not necessarily required and other configurations are contemplated herein. In an embodiment, each of the sub pixels SP1, SP2, SP3 and are centered on the center line C.

Referring to FIG. 2, a light emitting diode 200 may be disposed in the emitting area EA of each of the first, second, and third sub-pixels SP1, SP2, and SP3. The light emitting diode 200 may include a buffer layer 210, a plurality of p-type electrodes 250, and an n-type electrode 260. Also, a plurality of p-type electrodes 250 may include a first p-type electrode 251 and a second p-type electrode 252.

The buffer layer 210 may be disposed in common in the first and second emitting areas EA1 and EA2. Also, the first p-type electrode 251, the second p-type electrode 252, and the n-type electrode 260 are disposed on the buffer layer 210 and may be spaced apart from each other.

The first p-type electrode 251 may be disposed on one side (i.e, a left side) of the buffer layer 210, the second p-type electrode 252 may be disposed on the other side (i.e., a right side) of the buffer layer 210, and the n-type electrode 260 may be disposed on a center of the buffer layer 210. Furthermore, the first p-type electrode 251 is disposed in the first emitting area EA1, the second p-type electrode 252 is disposed in the second emitting area EA2, and the n-type electrode 260 may be disposed in boundary areas of the first and second emitting areas EA1 and EA2. In an embodiment, the buffer layer 210 is centered on the center line C. As the n-type electrode 260 is preferably centered on the buffer layer 210, the n-type electrode 260 is likewise centered on the center line C with half of the n-type electrode 260 disposed in the first emitting area EA1 and the other half of the n-type electrode 260 disposed in the second emitting area EA2. The n-type electrode 260 is therefore disposed in each of the emitting areas EA1, EA2 at the interface or boundary with the center line C that divides the emitting areas EA1, EA2 from each other.

Referring to FIG. 3, the connection electrode 300 may be disposed on the light emitting diode 200. The connection electrode 300 may include a first, second third connection electrodes 310, 320, 330. The first, second, and third connection electrodes 310, 320, 330 may also be referred to as sub-electrodes 310, 320, 330 of the connection electrode 300 for clarity.

The first connection electrode 310 may be disposed in each of the first, second, and third sub-pixels SP1, SP2, and SP3. Also, in at least one sub-pixel SP and in some embodiments, all of the sub-pixels SP1, SP2, and SP3, the first connection electrode 310 may be disposed in the first emitting area EA1. That is, in at least one sub-pixel SP, the first connection electrode 310 may overlap the first p-type electrode 251 and may not overlap the second p-type electrode 252 and the n-type electrode 260. Thus, the first connection electrode 310 may include an outermost edge or side that terminates before overlapping with the n-type electrode 260 and is therefore spaced from the n-type electrode 260. In an embodiment, the outermost edge of the first connection electrode 310 is disposed between a boundary of the first p-type electrode 251 and a boundary of the n-type electrode 260. Also, in at least one sub-pixel SP, the first connection electrode 310 may apply a voltage supplied through the first contact hole CT1 to the first p-type electrode 251. For example, the first connection electrode 310 disposed in the first sub-pixel SP1 may apply the voltage to the first p-type electrode 251 disposed in the first sub-pixel SP1 via the first contact hole CT1.

The second connection electrode 320 may be disposed in each of the first, second, and third sub-pixels SP1, SP2, and SP3. Also, in at least one sub-pixel SP and in some embodiments, all of the sub-pixels SP1, SP2, and SP3, the second connection electrode 320 may be disposed in the second emitting area EA2. That is, in at least one sub-pixel SP, the second connection electrode 320 may overlap the second p-type electrode 252 and may not overlap the first p-type electrode 251 and the n-type electrode 260. As such, the second connection electrode 320 may have a similar structure, arrangement, and orientation in the second emitting area EA2 as the first connection electrode 310 has in the first emitting area EA1 with an outermost edge or side of the second electrode 320 disposed between the second p-type electrode 252 and the n-type electrode 260. Also, in at least one sub-pixel SP, the second connection electrode 320 may apply a voltage supplied through a second contact hole CT2 to the second p-type electrode 252. For example, the second connection electrode 320 disposed in the first sub-pixel SP1 may apply the voltage to the second p-type electrode 252 disposed in the first sub-pixel SP1 via the second contact hole CT2.

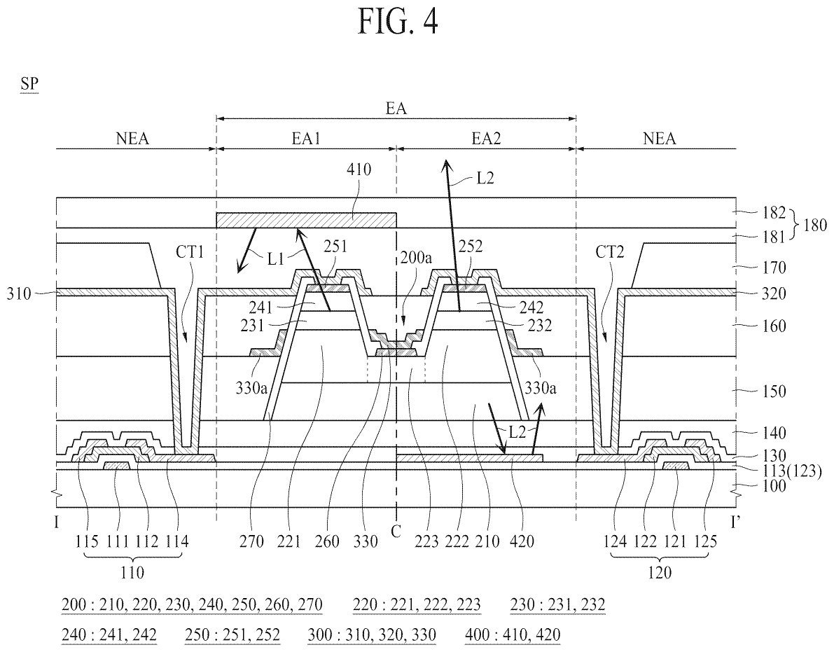

The third connection electrode 330 may be commonly disposed in the first, second, and third sub-pixels SP1, SP2, and SP3. Also, the third connection electrode 330 may be disposed in the boundary area of the first and second emitting areas EA1 and EA2. That is, in each of the first, second, and third sub-pixels SP1, SP2, and SP3, the third connection electrode 330 may overlap the n-type electrode 260 and may not overlap the first p-type electrode 251 and the second p-type electrode 252. Also, the third connection electrode 330 may be electrically connected to the common voltage line through a third contact hole CT3. Accordingly, the third connection electrode 330 may commonly apply the voltage supplied from the common voltage line to the n-type electrodes 260 disposed in each of the first, second, and third sub-pixels SP1, SP2, and SP3. In an embodiment, the third connection electrode 330 is disposed on or otherwise connected to each of the n-type electrodes 260 in each of first, second, and third sub-pixels SP1, SP2, and SP3. Thus, the third connection electrode 330 acts a bus or common transmission line that distributes the voltage from the common voltage line to the n-type electrodes 260. While the third connection electrode 330 is illustrated as also overlapping the first and second connection electrodes 310, 320, the third connection electrode 330 is electrically isolated from the first and second connection electrodes 310, 320 by the configuration of the layer stack of the pixels P and/or sub-pixels SP, as further described with reference to FIG. 4.

The light emitting diode 200 and the connection electrode 300 will be described in detail later.

FIG. 4 is a cross-sectional view of the first sub-pixel SP1 taken along line I-I′ in FIG. 3. In an embodiment, the structure of the first sub-pixel SP1 is generally representative of any other sub-pixel in the display device 10 and thus may be referred to below as a generic sub-pixel SP.

Referring to FIG. 4, the sub-pixel SP according to an embodiment of the present disclosure may include a substrate 100, a first thin film transistor 110, a second thin film transistor 120, an interlayer insulating layer 130, a passivation layer 140, first and second planarization layers 150 and 160, a bank 170, an encapsulation layer 180, a light emitting diode 200, a plurality of connection electrodes 300, and a plurality of reflection layers 400.

The substrate 100 may be formed of glass or plastic, but is not limited thereto. The display device according to an embodiment of the present disclosure may be formed in a dual side emission type in which the generated light is emitted in upper and lower directions (i.e., up and down in the orientation of FIG. 4). Accordingly, a transparent material may preferably be used as a material of the substrate 100.

First and second thin film transistors 110 and 120 may be disposed on the substrate 100. The first thin film transistor 110 may be disposed in the non-emitting area NEA adjacent to the first emitting area EA1, and the second thin film transistor 120 may be disposed in the non-emitting area NEA adjacent to the second emitting area EA2. Each of the first and second thin film transistors 110 and 120 may include a gate electrode 111 and 121, a semiconductor layer 112 and 122, a gate insulation layer 113 and 123, a source electrode 114 and 124, and a drain electrode 115 and 125. Since the first and second thin film transistors 110 and 120 include the same configuration, only the configuration of the first thin film transistor 110 will be described.

The gate electrode 111 of the first thin film transistor 110 may be disposed on the substrate 100. Also, the semiconductor layer 112 may be disposed on the gate electrode 111. The semiconductor layer 112 may include a poly-silicon semiconductor or an oxide semiconductor. Also, when the semiconductor layer 112 includes an oxide semiconductor, at least one oxide of IGZO (indium-gallium-zinc-oxide), IZO (indium-zinc-oxide), IGTO (indium-gallium-tin-oxide), and IGO (indium-gallium-oxide) may be included.

For insulating the gate electrode 111 and the semiconductor layer 112, the gate insulation layer 113 may be disposed between the gate electrode 111 and the semiconductor layer 112. The gate insulation layer 113 may be formed of a single layer of silicon nitride (SiNx) or silicon oxide (SiOx), or multiple layers thereof. Also, FIG. 4 discloses a bottom gate structure in which the semiconductor layer 112 is disposed on the gate electrode 111, but is not limited thereto. For example, a top gate structure in which the gate electrode 111 is disposed on the semiconductor layer 112 may be disclosed.

The source electrode 114 and the drain electrode 115 may be disposed on the semiconductor layer 112 while facing each other. Also, the interlayer insulating layer 130 may be disposed on the source electrode 114 and the drain electrode 115. A contact hole exposing a portion of the source electrode 114 may be disposed in the interlayer insulating layer 130, and may be a part of the first contact hole CT1 described further below. Also, the interlayer insulating layer 130 may be formed of an inorganic insulating material such as silicon oxide (SiOx), silicon nitride (SiNx), silicon oxynitride (SiOxNy), or the like. Likewise, a contact hole exposing a portion of the source electrode 124 of the second thin film transistor 120 may be disposed in the interlayer insulating layer 130, which may be a part of the second contact hole CT2 described further below.

The passivation layer 140 may be disposed on the first and second thin film transistors 110 and 120. The passivation layer 140 may compensate for the step difference caused by the first and second thin film transistors 110 and 120 to form upper regions of the first and second thin film transistors 110 and 120 to be flat. Thus, the passivation layer 140 may also be referred to as a planarization layer. Furthermore, the passivation layer 140 may be formed of an organic insulating material such as acrylic resin, epoxy resin, phenolic resin, polyamide resin, polyimide resin, or the like, and may further include an organic insulating material having an adhesive component to fix the light emitting diode 200 on the passivation layer 140.

The light emitting diode 200 may be disposed on the passivation layer 140 and may be disposed in boundary regions of the first and second emitting regions EA1 and EA2, meaning proximate to or adjacent to the center line C dividing the first and second emitting regions EA1, EA2 within the larger emitting region EA. The light emitting diode 200 may include a buffer layer 210, an n-type semiconductor layer 220, a plurality of active layers 230, a plurality of p-type semiconductor layers 240, a plurality of p-type electrodes 250, an n-type electrode 260, and a protective layer 270.

The buffer layer 210 may be disposed on the passivation layer 140 and may be disposed in the first and second emitting regions EA1 and EA2. A top surface of the buffer layer 210 may be flat. Also, the buffer layer 210 may reduce a characteristic difference between the passivation layer 140 and the n-type semiconductor layer 220, thereby reducing defects in the display device 10. The buffer layer 210 may be formed of an undoped semiconductor material such as GaN, AlGaN, InGaN, AlInGaN, or the like.

The n-type semiconductor layer 220 may be disposed on the buffer layer 210 and may be disposed in the first and second emitting regions EA1 and EA2. A groove 200a or channel 200a may be formed in an upper surface of the n-type semiconductor layer 220. The groove 200a may be disposed at a center of the n-type semiconductor layer 220 and may be disposed in boundary regions of the first and second emitting regions EA1 and EA2. In an embodiment, the groove 200a is centered on the center line C.

The n-type semiconductor layer 220 may include a first protrusion portion 221, a second protrusion portion 222, and a concave portion 223 defined by the groove 200a.

The first protrusion portion 221 is on one side area (i.e., a left side area) of the n-type semiconductor layer 220 relative to the center line C and may be disposed in the first emitting area EA1. Also, the second protrusion portion 222 is on the other side area (i.e., a right side area) of the n-type semiconductor layer 220 relative to the center line C and may be disposed in the second emitting area EA2. That is, the first protrusion portion 221 may be in an area adjacent to one side (i.e., adjacent to a left side) of the groove 200a, and the second protrusion portion 222 may be in an area adjacent to the other side (i.e., adjacent to a right side) of the groove 200a. The first and second protrusion portions 221 and 222 are not in direct contact with each other.

The concave portion 223 may be an area in which the groove 200a is disposed, meaning that the n-type semiconductor layer 220 may initially be deposited as a flat and planar layer on the buffer layer, and the groove 200a is formed in a center of the layer to define the protrusion portions 221, 222 on either side of the groove 200a, and the concave portion 223 being under or at the bottom of the groove 200a between the protrusion portions 221, 222. The concave portion 223 is a central area of the n-type semiconductor layer 220 (i.e., centered on center line C), and may be disposed in a boundary area between the first and second emitting areas EA1 and EA2. Also, the concave portion 223 may be in contact with side surfaces of the first and second protrusion portions 221 and 222. That is, the concave portion 223 may be disposed between the first and second protrusion portions 221 and 222. Thus, while the protrusion portions 221, 222 are not in contact with each other, they are connected by the concave portion 223 and spaced apart from each by the concave portion 223 in a single, continuous layer with varying heights or thickness across the layer (i.e., the protrusion portions 221, 222 are taller or thicker and the concave portion 223 is shorter or thinner as a result of the groove 200a). As such, the n-type semiconductor layer 220 has an overall “U” shape.

Also, the n-type semiconductor layer 220 may provide electrons to a plurality of active layers 230. The n-type semiconductor layer 220 may be formed of an n-GaN-based semiconductor material such as GaN, AlGaN, InGaN, or AlInGaN. Also, Si, Ge, Se, Te, C, or the like may be used as an impurity used for doping the n-type semiconductor layer 220.

A plurality of active layers 230 may be disposed in or on the n-type semiconductor layer 220 and may be disposed in either or both the first and second emitting areas EA1 and EA2. Also, a plurality of active layers 230 may include first and second active layers 231 and 232. The first active layer 231 may be disposed on the first protrusion portion 221 of the n-type semiconductor layer 220 and may be disposed in the first light emitting area EA1. Also, the second active layer 232 may be disposed on the second protrusion portion 222 of the n-type semiconductor layer 220 and may be disposed in the second light emitting area EA2. The first and second active layers 231 and 232 may be spaced apart from each other and may be driven independently.

A plurality of active layers 230 may be light emitting layers that emit light. The first active layer 231 may emit a first light L1, and the second active layer 232 may emit a second light L2, as schematically illustrated by arrows L1, L2. Also, the plurality of active layers 230 may have a multi-quantum well (MQW) structure having a well layer and a barrier layer having a higher band gap than the well layer. For example, a plurality of active layers 230 may have a multi-quantum well structure such as InGaN/GaN, but are not limited thereto.

A plurality of p-type semiconductor layers 240 may be disposed on the plurality of active layers 230 and may be disposed in either or both the first and second emitting regions EA1 and EA2. Also, the plurality of p-type semiconductor layers 240 may include first and second p-type semiconductor layers 241 and 242. The first p-type semiconductor layer 241 may be disposed on the first active layer 231 and may be disposed in the first emitting region EA1. Also, the second p-type semiconductor layer 242 may be disposed on the second active layer 232 and may be disposed in the second emitting region EA2. Also, the first and second p-type semiconductor layers 241 and 242 may be spaced apart from each other and may be driven independently.

A plurality of p-type semiconductor layers 240 may provide holes to a plurality of active layers 230. A plurality of p-type semiconductor layers 240 may be formed of a p-GaN-based semiconductor material such as GaN, AlGaN, InGaN, or AlInGaN. Also, Mg, Zn, Be, or the like may be used as an impurity used for doping a plurality of p-type semiconductor layers 240.

A plurality of p-type electrodes 250 may be disposed on the plurality of p-type semiconductor layers 240 and may be disposed in either or both the first and second emitting regions EA1 and EA2. Also, the plurality of p-type electrodes 250 may include first and second p-type electrodes 251 and 252. The first p-type electrode 251 may be disposed on the first p-type semiconductor layer 241 and may be disposed in the first emitting region EA1. Also, the second p-type electrode 252 may be disposed on the second p-type semiconductor layer 242 and may be disposed in the second emitting region EA2. Also, the first and second p-type electrodes 251 and 252 may be spaced apart from each other and may be driven independently.

That is, the first active layer 231, the first p-type semiconductor layer 241, and the first p-type electrode 251 may be sequentially disposed from bottom to top on the first protrusion 221 of the n-type semiconductor layer 220. Also, the second active layer 232, the second p-type semiconductor layer 242, and the second p-type electrode 252 may be sequentially disposed from bottom to top on the second protrusion 222 of the n-type semiconductor layer 220.

The n-type electrode 260 may be disposed on the concave portion 223 of the n-type semiconductor layer 220 and may be disposed in boundary regions of the first and second emitting regions EA1 and EA2 on either adjacent side of the center line C. Also, the n-type electrode 260 may face side surfaces of the first and second protrusion portions 221 and 222 of the n-type semiconductor layer 220.

Each of the plurality of p-type electrodes 250 and n-type electrodes 260 may include a transparent conductive material such as an indium tin oxide (ITO) or an indium zinc oxide (IZO).

The protective layer 270 may cover a top surface and side surfaces of the light emitting diode 200. Specifically, the protective layer 270 may cover top surface and side surfaces of the n-type semiconductor layer 220, the plurality of active layers 230, and the plurality of p-type semiconductor layers 240 and their component parts or layer stacks described above. Also, the protective layer 270 may cover side surfaces of the plurality of p-type electrodes 250 and the n-type electrode 260 and expose a partial region of the top surface of the plurality of p-type electrodes 250 and the n-type electrode 260. The protective layer 270 may be disposed or comprised of an inorganic insulating material such as silicon oxide (SiOx), silicon nitride (SiNx), silicon oxynitride (SiOxNy), or the like.

The first planarization layer 150 may be disposed on the passivation layer 140, and may be disposed in the emitting area EA and the non-emitting area NEA. The first planarization layer 150 may be surround a side surface of the light emitting diode 200 to stably fix the light emitting diode 200 on the passivation layer 140. Also, the distance from the substrate 100 to the upper surface of the first planarization layer 150 may be smaller than the distance from the substrate 100 to the upper surface of the n-type electrode 260. That is, the position of the upper surface of the first planarization layer 150 may be lower than the position of the upper surface of the n-type electrode 260 in the layer stack. Accordingly, the upper surface of the n-type electrode 260 may be exposed by the first planarization layer 150 or extend beyond the first planarization layer 150.

The second planarization layer 160 may be disposed on the first planarization layer 150 and may be disposed in the emitting area EA and the non-emitting area NEA. The second planarization layer 160 may cover the top surface and side surfaces of the light emitting diode 200. Also, the second planarization layer 160 may fill the inside of the groove 200a of the light emitting diode 200. Thus, the second planarization layer 160 may compensate for the step difference of the upper portion of the light emitting diode 200 that extends beyond the first planarization layer 150. Also, the second planarization layer 160 may expose the top surfaces of the plurality of p-type electrodes 250 of the light emitting diode 200.

Each of the first and second planarization layers 150 and 160 may be formed of an inorganic insulating material or an organic insulating material. Also, each of the first and second planarization layers 150 and 160 may include different materials or may include the same material.

The plurality of connection electrodes 300 are disposed in the emitting area EA and the non-emitting area NEA, and may include first, second and third connection electrodes 310, 320 and 330. Each of the first, second and third connection electrodes 310, 320 and 330 may include a transparent conductive material such as an indium tin oxide (ITO) or an indium zinc oxide (IZO).

The first connection electrode 310 may be disposed on the second planarization layer 160 and may be disposed in the first emitting area EA1 and the non-light emitting area NEA. The first connection electrode 310 may be in contact with the source electrode 114 of the first thin film transistor 110 through a first contact hole CT1. The first contact hole CT1 may be disposed in the non-emitting area NEA adjacent to the first emitting area EA1. Also, the first contact hole CT1 may penetrate through the interlayer insulating layer 130, the passivation layer 140, and the first and second planarization layers 150 and 160 to expose the source electrode 114 of the first thin film transistor 110 to the outside and enable an electrical connection between the first connection electrode 310 and the source electrode 114 of the first thin film transistor 110 through the various layers described above. Also, the first connection electrode 310 may be in contact with the first p-type electrode 251. Accordingly, the first p-type electrode 251 and the source electrode 114 of the first thin film transistor 110 may be electrically connected through the first connection electrode 310 and the contact hole CT1.

The second connection electrode 320 may be disposed on the second planarization layer 160 and may be disposed in the second emitting area EA2 and the non-emitting area NEA. The second connection electrode 320 may be in contact with the source electrode 124 of the second thin film transistor 120 through a second contact hole CT2. The second contact hole CT2 may be disposed in the non-emitting area NEA adjacent to the second emitting area EA2. Also, the second contact hole CT2 may penetrate through the interlayer insulating layer 130, the passivation layer 140, and the first and second planarization layers 150 and 160 to expose the source electrode 124 of the second thin film transistor 120 to the outside and enable an electrical connection between the first connection electrode 310 and the source electrode 124 of the second thin film transistor 120 through the various layers described above. Also, the second connection electrode 320 may be in contact with the second p-type electrode 252. Accordingly, the second p-type electrode 252 and the source electrode 124 of the second thin film transistor 120 may be electrically connected through the second connection electrode 320 and the contact hole CT2.

That is, the first p-type electrode 251 may be electrically connected to the first thin film transistor 110, and the second p-type electrode 252 may be electrically connected to the second thin film transistor 120. Accordingly, the first and second p-type electrodes 251 and 252 may receive different voltages from different thin film transistors. Also, the first and second connection electrodes 310 and 320 may be spaced apart from each other on opposite sides of the emitting area EA and/or opposite sides of the center line C.

The third connection electrode 330 may be disposed on the first planarization layer 150, and may be disposed in boundary regions of the first and second emitting regions EA1 and EA2, meaning the third connection electrode 330 is centered on the center line C and extends into both edge areas of the first and second emitting regions EA1, EA2. Also, the third connection electrode 330 may be covered with a second planarization layer 160. The third connection electrode 330 may be in contact with the upper surface of the n-type electrode 260. Also, as described above in FIG. 3, the third connection electrode 330 may be electrically connected to the common voltage line through the third contact hole CT3. Thus, the n-type electrode 260 and the common voltage line may be electrically connected through the third connection electrode 330.

Therefore, different voltage levels applied to each of the source electrode 114 of the first thin film transistor 110 and the common voltage line may be transferred to the first p-type electrode 251 and the n-type electrode 260 through the first and third connection electrodes 310 and 330. Accordingly, the first active layer 231 may emit light, and specifically light L1. Furthermore, different voltage levels applied to each of the source electrode 124 of the second thin film transistor 120 and the common voltage line may be transferred to the second p-type electrode 252 and the n-type electrode 260 through the second and third connection electrodes 320 and 330. Accordingly, the second active layer 232 may emit light, and specifically light L2. That is, since the first and second active layers 231 and 232 are driven by different thin film transistors, the first and second active layers 231 and 232 may emit light independently and are independently controlled.

Each of a plurality of p-type electrodes 250 and an n-type electrode 260 may include a metal material such as Au, W, Pt, Si, Ir, Ag, Cu, Ni, Ti, or Cr, and an alloy thereof. Each of a plurality of p-type electrodes 250 and an n-type electrode 260 may include a transparent conductive material such as an indium tin oxide (ITO) or an indium zinc oxide (IZO).

The bank 170 may be disposed on the first and second connection electrodes 310 and 320 and may be disposed in the non-emitting area NEA. The bank 170 may be formed of an inorganic insulating material, and may include a material that absorbs light. Also, the bank 170 may overlap the first and second planarization layers 150 and 160, and thus a thickness of the bank 170 may be minimized. Accordingly, light leakage between adjacent sub-pixels may be prevented while minimizing light absorption by the bank 170.

The encapsulation layer 180 may be disposed on the bank 170 and the light emitting diode 200, and may be disposed in the emitting area EA and the non-emitting area NEA. Also, the encapsulation layer 180 may include first and second encapsulation layers 181 and 182. The encapsulation layer 180 may compensate for the step difference by the bank 170 and the light emitting diode 200 to form upper regions of the bank 170 and the light emitting diode 200 to be flat or to planarize upper regions of the bank 170 and the light emitting diode 200. Also, the step difference by the first and second contact holes CT1 and CT2 may be compensated for or planarized by the encapsulation layer 180.

The encapsulation layer 180 may transmit light emitted from the light emitting diode 200. The encapsulation layer 180 may include a transparent organic insulating material, such as an acrylic resin, an epoxy resin, a phenolic resin, a polyamide resin, or a polyimide resin.

The plurality of reflective layers 400 may include first and second reflective layers 410 and 420.

The first reflective layer 410 may be disposed on the first encapsulation layer 181 and may be covered with the second encapsulation layer 182. Thus, the first reflective layer 410 is generally located in an upper portion or at a top of the multi-layer stack of the sub-pixel SP. Also, the first reflective layer 410 may be disposed in the first emitting area EA1 and may not be disposed in the second emitting area EA2. The first reflective layer 410 may overlap the first protrusion 221 of the n-type semiconductor layer 220. That is, the first reflective layer 410 may also overlap the first active layer 231, the first p-type semiconductor layer 241, and the first p-type electrode 251. Also, the width of the first reflective layer 410 may be greater than the width of the first protrusion 221. In an embodiment, the first reflective layer 410 has a width that is approximate to, or equal to, a width of the first emitting area EA1 from the center line C to an interface with the non-emitting area NEA to the left of the center line C. The interface of the non-emitting area NEA and the first emitting area EA1 may be at an outer edge or side of the source electrode 114 of the first transistor 110 that faces toward the center line C.

When the first light L1 generated by the first active layer 231 of the light emitting diode 200 is emitted toward the encapsulation layer 180, the first reflective layer 410 may reflect the first light L1 toward the substrate 100 in a generally downward direction. In this case, since the substrate 100 is formed of a transparent material, the first light L1 reflected by the first reflective layer 410 may be transmitted in a lower direction of the substrate 100 and outward through the substrate 100. Accordingly, since the first light L1 is emitted in a lower direction of the display device, the first light emitting area EA1 may emit light in a lower direction of the display device 10, meaning in a vertically downward direction in the orientation of FIG. 4.

The second reflective layer 420 may be disposed on the gate insulating layers 113 of the first thin film transistors 110 and the gate insulating layers 123 of the second thin film transistors 120 and may be covered with an interlayer insulating layer 130. Thus, the second reflective layer 420 is generally located in a lower portion or a bottom of the multi-layer stack of the sub-pixel SP and on an opposite side of the multi-layer stack from the first reflective layer 410. Furthermore, the second reflective layer 420 may be disposed in the second emitting area EA2 and may not be disposed in the first emitting area EA1. The second reflective layer 420 may overlap the second protrusion portion 222 of the n-type semiconductor layer 220. That is, the second reflective layer 420 may overlap the second active layer 232, the second p-type semiconductor layer 242, and the second p-type electrode 252. Furthermore, the width of the second reflective layer 420 may be greater than the width of the second protrusion portion 222. In an embodiment, the second reflective layer 420 has a width that is approximate to, or equal to, a width of the second emitting area EA2 from the center line C to an interface with the non-emitting area NEA to the right of the center line C. The interface of the non-emitting area NEA and the second emitting area EA2 may be at an outer edge or side of the source electrode 124 of the second transistor 110 that faces toward the center line C. In a further embodiment, such as that shown in FIG. 4, the second reflective layer 420 may have a width that is less than an entirety of the second emitting area EA2, and thus may have a width less than the first reflective layer 410.

When the second light L2 generated in the second active layer 232 of the light emitting diode 200 is emitted toward the substrate 100, the second reflective layer 420 may reflect the second light L2 toward the encapsulation layer 180 in a generally upward direction. In this case, since the encapsulation layer 180 is formed of a transparent material, the second light L2 reflected by the second reflective layer 420 may be transmitted in an upper direction of the encapsulation layer 180 and outward through the encapsulation layer 180. Accordingly, since the second light L2 is emitted in an upper direction of the display device, the second emitting area EA2 may emit light in an upper direction of the display device, meaning in a vertically upward direction in the orientation of FIG. 4.

In an embodiment, the reflective layers 410, 420 are both positioned adjacent to, and extending away from, the center line C across the first and second emitting areas EA1, EA2 with the first reflective layer 410 at the top of the sub-pixel SP and the second reflective layer 420 at the bottom of the sub-pixel SP. Thus, the reflective layers 410, 420 are mirror images of each other across the center line C on opposite sides of the multi-layer stack of the sub-pixel SP.

Each of the first and second reflective layers 410 and 420 may include a metal material such as Au, W, Pt, Si, Ir, Ag, Cu, Ni, Ti, or Cr, and an alloy thereof. Alternatively, each of the first and second reflective layers 410 and 420 may include a transparent conductive material such as an indium tin oxide (ITO) or an indium zinc oxide (IZO). Also, each of the first and second reflective layers 410 and 420 may be disposed as a single layer or multiple layers. For example, each of the first and second reflective layers 410 and 420 may be formed as a triple layer in which a transparent conductive material, a metal material, and a transparent conductive material are sequentially stacked.

The second reflective layer 420 may be formed by the same process as the source electrodes 114 and the drain electrodes 115 of the first thin film transistors 110 and the source electrodes 124 and the drain electrodes 125 of the second thin film transistors 120, and may be formed of the same material. Also, although FIG. 4 shows that the second reflective layer 420 is disposed on the gate insulating layers 113 and 123, the present disclosure is not limited thereto. For example, the second reflective layer 420 may be disposed on the interlayer insulating layer 130.

In conclusion, an embodiment of the present disclosure discloses emitting light in lower and upper directions of a display device using a single light emitting diode 200. Specifically, the present disclosure may drive each of the first and second active layers 231 and 232 independently disposed in one light emitting diode 200 and reflect the light emitted by the independently driven active layers 231, 232 in opposite directions. Accordingly, the first light L1 generated in the first active layer 231 may be emitted to the first light emitting area EA1, and the second light L2 generated in the second active layer 232 may be emitted to the second light emitting area EA2. Also, first and second reflective layers 410 and 420 may be disposed in the first and second light emitting areas EA1 and EA2. Accordingly, light may be emitted in lower and upper directions of the display device by adjusting the paths of the first and second light L1 and L2.

Therefore, even when a plurality of light emitting diodes are not disposed in one sub-pixel, and the sub-pixel instead includes only a single light emitting diode, the light may be emitted simultaneously in lower and upper directions of the display device. That is, while simplifying the process, both the upper direction and the opposite lower direction of the display device may emit light without reducing the resolution of the display device. Accordingly, the display device of the present disclosure may improve the quality of the display device by emitting the light in both directions.

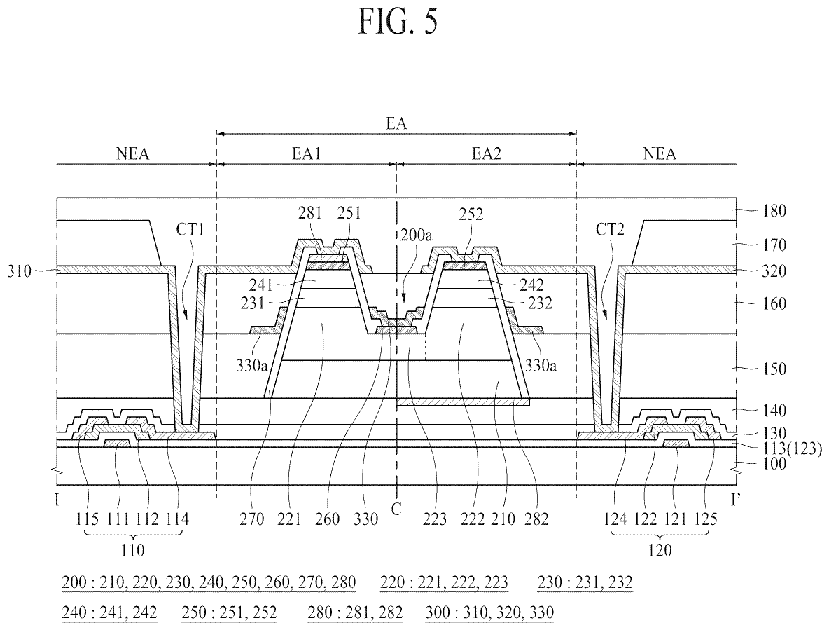

FIG. 5 is a cross-sectional view of a sub-pixel SP according to another embodiment of the present disclosure.

Compared with FIG. 4, FIG. 5 discloses substantially the same structure except for the structure of the reflective members 281 and 282. Accordingly, the same reference numerals are used for elements that are the same as those of the first sub-pixel SP1 illustrated in FIG. 4, and repeated descriptions are omitted. Also, compared with FIG. 4, FIG. 5 may not include the reflective layer 400.

As described above in FIG. 4, the light emitting diode 200 may be disposed on the passivation layer 140, and may be disposed in boundary regions of the first and second light emitting regions EA1 and EA2. Also, the light emitting diode 200 may include a buffer layer 210, the n-type semiconductor layer 220, a plurality of active layers 230, a plurality of p-type semiconductor layers 240, a plurality of p-type electrodes 250, the n-type electrode 260, and the protective layer 270.

In this case, the light emitting diode 200 may further include a reflective member 280 instead of the sub-pixel SP including the reflective layer 400. The reflective member 280 may further include first and second reflective members 281 and 282.

The first reflective member 281 may be disposed on the first p-type electrode 251. The first reflective member 281 may be disposed in the first emitting area EA1 and may not be disposed in the second emitting area EA2. Also, the upper surface of the first reflective member 281 may be exposed by the protective layer 270. The first reflective member 281 may include a metal material such as Au, W, Pt, Si, Ir, Ag, Cu, Ni, Ti, or Cr, and an alloy thereof.

As described above in FIG. 4, the first connection electrode 310 may be in contact with the source electrode 114 of the first thin film transistor 110 through the first contact hole CT1. Also, the first connection electrode 310 may be in contact with the first reflective member 281. Since the first reflective member 281 is made of metal, the first reflective member 281 may function as an electrode together with the first p-type electrode 251. Accordingly, the first p-type electrode 251 and the source electrode 114 of the first thin film transistor 110 may be electrically connected through the first connection electrode 310 and the first reflective member 281.

When the first light L1 generated by the first active layer 231 of the light emitting diode 200 is emitted to face the encapsulation layer 180 (FIG. 4), the first reflective member 281 may reflect the first light L1 toward the substrate 100. In this case, since the substrate 100 is formed of the transparent material, the first light L1 reflected by the first reflective member 281 may be transmitted in a lower direction of the substrate 100. Accordingly, since the first light L1 is emitted in a lower direction of the display device, the first emitting area EA1 may emit light in a lower direction of the display device.

Also, FIG. 5 discloses disposing the first reflective member 281 made of a metal material on the first p-type electrode 251 made of a transparent conductive material, but is not limited thereto. For example, both the first p-type electrode 251 and the first reflective member 281 may be made of a metal material. In this case, the first p-type electrode 251 and the first reflective member 281 may include the same metal material or different metal materials. In an embodiment, the first reflective member 281 has a width that is less than the first active layer 231 and less than the first p-type semiconductor layer 241.

The second reflective member 282 may be disposed on a lower surface of the buffer layer 210 and may overlap the second active layer 232. The second reflective member 282 may be disposed in the second emitting area EA2 and may not be disposed in the first emitting area EA1. The second reflective member 282 may include a metallic material such as Au, W, Pt, Si, Ir, Ag, Cu, Ni, Ti, or Cr, and an alloy thereof.

When the second light L2 generated in the second active layer 232 of the light emitting diode 200 is emitted toward the substrate 100 (FIG. 4), the second reflective member 282 may reflect the second light L2 toward the encapsulation layer 180. In this case, since the encapsulation layer 180 is formed of a transparent material, the second light L2 reflected by the second reflective member 282 may be transmitted in an upper direction of the encapsulation layer 180. Accordingly, since the second light L2 is emitted in an upper direction of the display device, the second light emitting area EA2 may emit light in an upper direction of the display device. In an embodiment, the second reflective member 282 may have a width that is greater than the first reflective member 282 and is generally similar to a width of the second reflective layer 420 described above.

As described above, since the passivation layer 140 is made of an organic insulating material, the passivation layer 140 may have fluidity before the curing process. In this case, when the light emitting diode 200 on which the second reflective member 282 is deposited is transferred on the passivation layer 140, a step difference caused by the second reflective member 282 may be compensated. Specifically, a concave shape may be formed in the upper surface of the passivation layer 140 to which the second reflective member 282 is transferred by the flow of the passivation layer 140. Accordingly, the light emitting diode 200 may be stably transferred on the passivation layer 140.

As in the embodiment of FIG. 4, FIG. 5 discloses emitting the light in lower and upper directions of the display device using the single light emitting diode 200. In this case, as compared with an embodiment of FIG. 4, FIG. 5 discloses the first and second reflective members 281 and 282 included in the light emitting diode 200, by omitting the reflective layer 400 formed in the display device. Specifically, the first reflective member 281 disposed on the first p-type electrode 251 and the second reflective member 282 disposed on the lower surface of the buffer layer 210 are disclosed. Therefore, as compared with an embodiment of FIG. 4, the manufacturing process of the display device in FIG. 5 may be further simplified. Other configurations and locations of the reflective layer 400 and the reflective member 280 are contemplated herein.

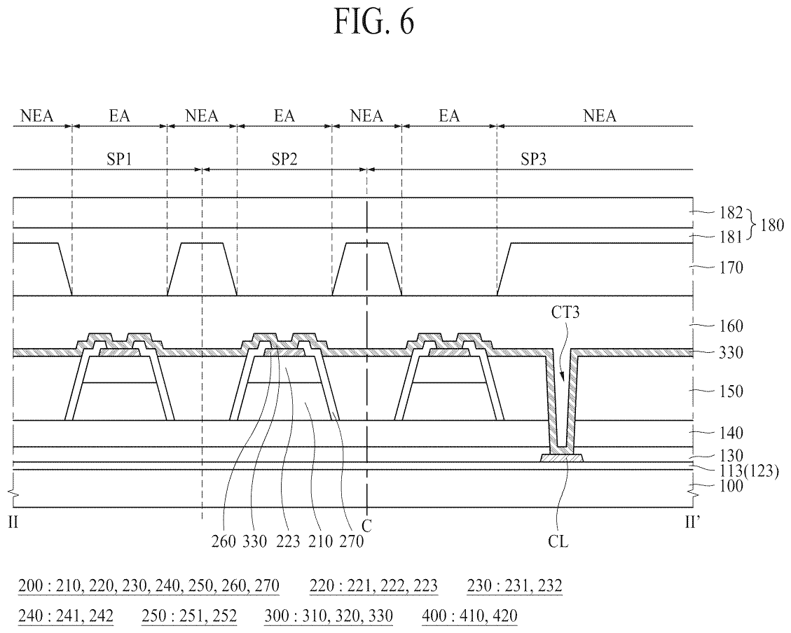

FIG. 6 is a cross-sectional view of one pixel P of the display device 10 taken along line II-II′ in FIG. 3.

Compared with FIG. 4, FIG. 6 discloses substantially the same structure as FIG. 4. Accordingly, the same reference numerals are used for components that are the same as those of the sub-pixel SP illustrated in FIG. 4, and repeated descriptions are omitted.

As described above with reference to FIGS. 2 and 3, each of the plurality of pixels P may include the first, second, and third sub-pixels SP1, SP2, and SP3. Also, each of the first, second, and third sub-pixels SP1, SP2, and SP3 may include the light emitting diode 200.

As described in FIG. 4, the light emitting diode 200 may include the buffer layer 210, the n-type semiconductor layer 220, a plurality of active layers 230, a plurality of p-type semiconductor layers 240, a plurality of p-type electrodes 250, the n-type electrode 260, and the protective layer 270. FIG. 6 illustrates the buffer layer 210, the concave portion 223 of the n-type semiconductor layer 220, the n-type electrode 260, and the protective layer 270. The n-type electrode 260 may be disposed on the concave portion 223 of the n-type semiconductor layer 220 and may be disposed in the emitting area EA.

The third connection electrode 330 may be disposed on the first planarization layer 150 and may be disposed in the emitting area EA and the non-emitting area NEA. Also, the third connection electrode 330 may be disposed in the non-emitting area NEA between the sub-pixels SP adjacent to each other. That is, the third connection electrode 330 may be commonly disposed in the first, second, and third sub-pixels SP1, SP2, and SP3.

The third connection electrode 330 may be in contact with an upper surface of the n-type electrode 260 of the light emitting diode 200 disposed in each of the first, second, and third sub-pixels SP1, SP2, and SP3. That is, the third connection electrode 330 may be commonly connected to the first, second, and third sub-pixels SP1, SP2, and SP3.

The third connection electrode 330 may be electrically connected to the common voltage line CL through a third contact hole CT3. The third contact hole CT3 may be disposed in the non-emission area NEA of the third sub-pixel SP3. Also, the third contact hole CT3 may penetrate the interlayer insulating layer 130, the passivation layer 140, and the first planarization layer 150 to expose the common voltage line CL to the outside and enable an electrical connection between the common voltage line CL and the third connection electrode 330 through the layers described above. Also, the second planarization layer 160 may cover the third contact hole CT3 and compensate for the step difference of the third contact hole CT3. Accordingly, the third connection electrode 330 may commonly apply the voltage supplied from the common voltage line CL to the n-type electrodes 260 disposed in the first, second, and third sub-pixels SP1, SP2, and SP3, respectively.

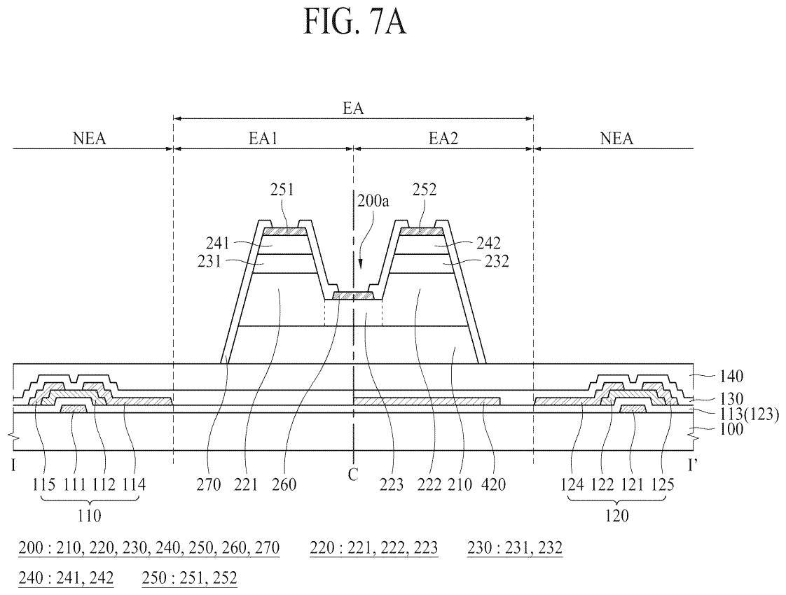

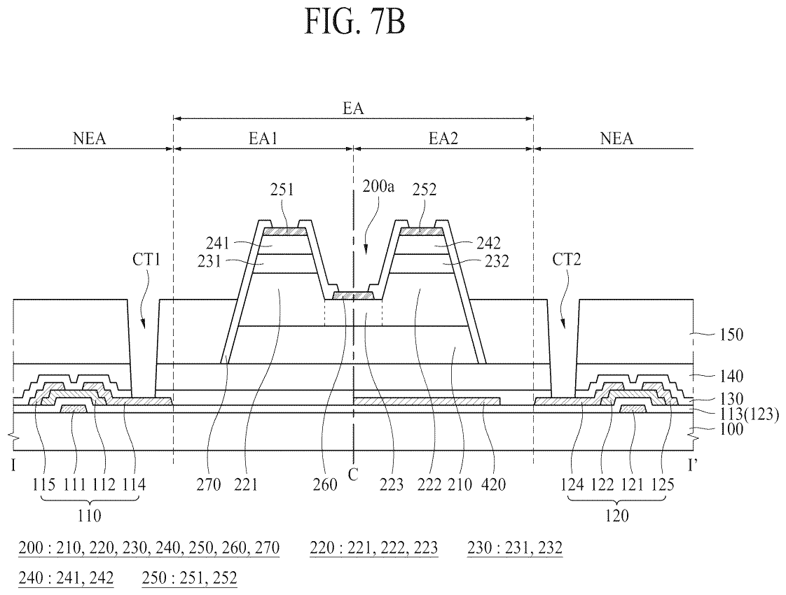

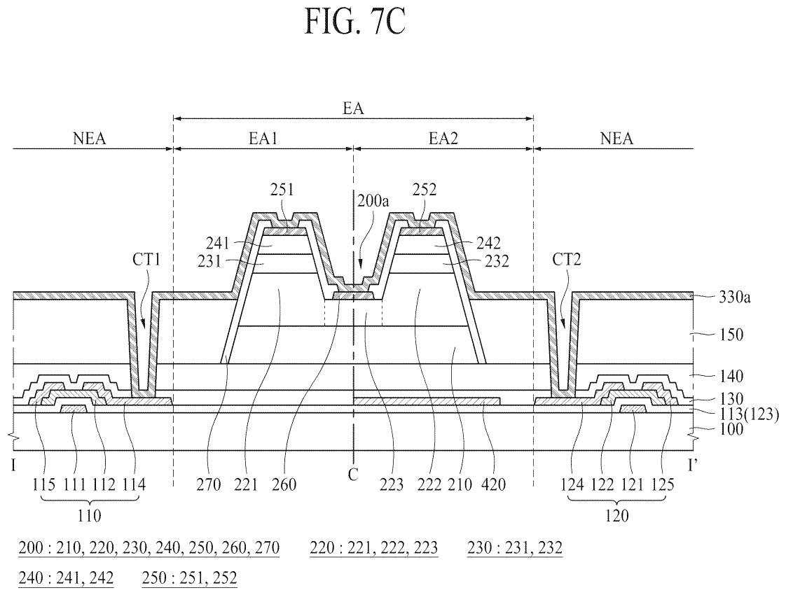

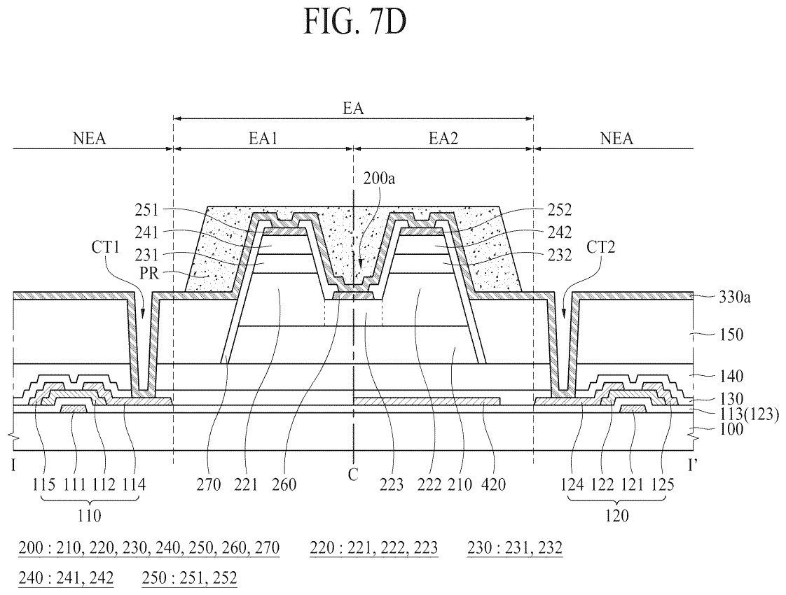

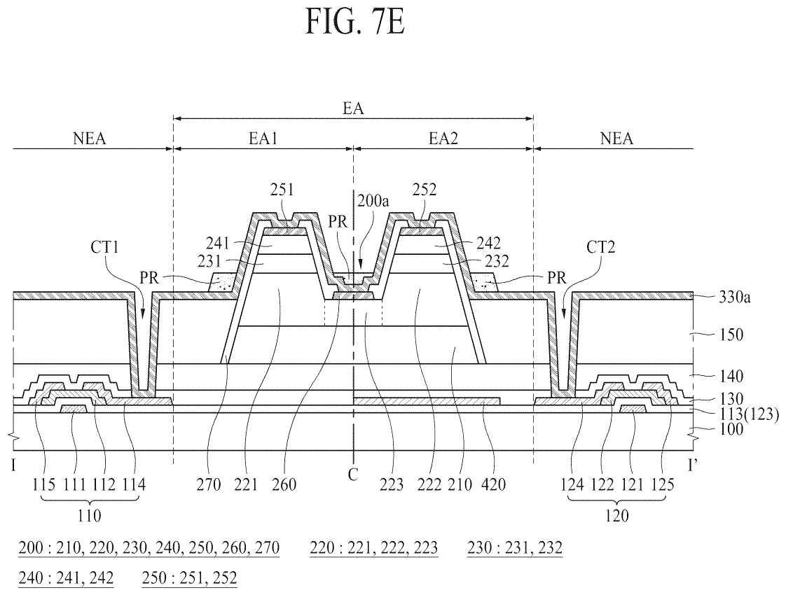

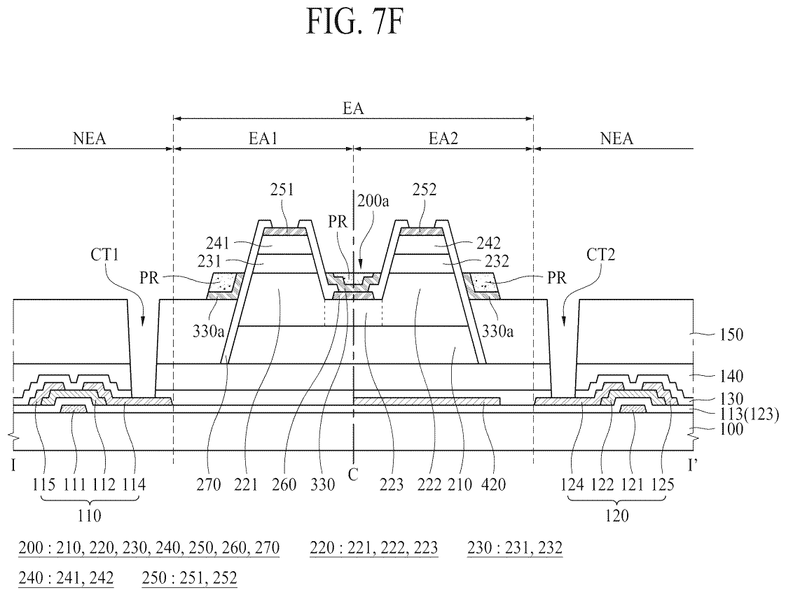

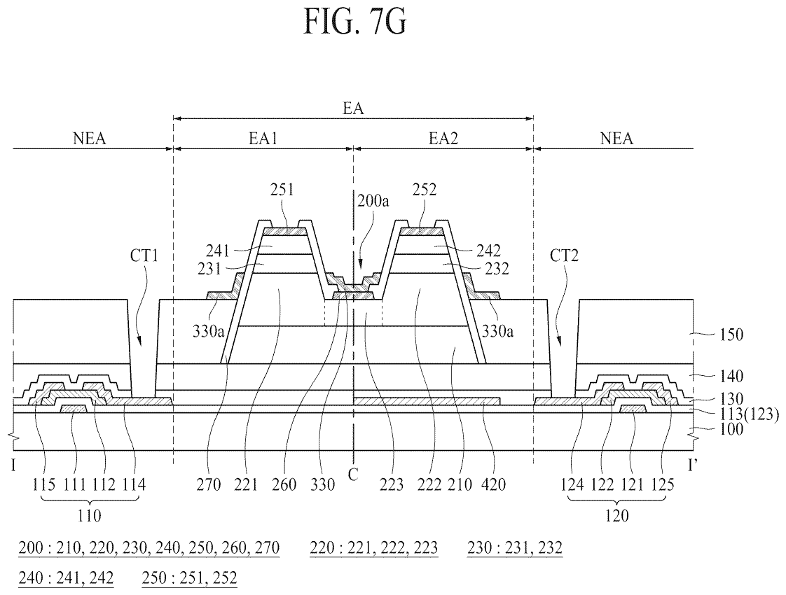

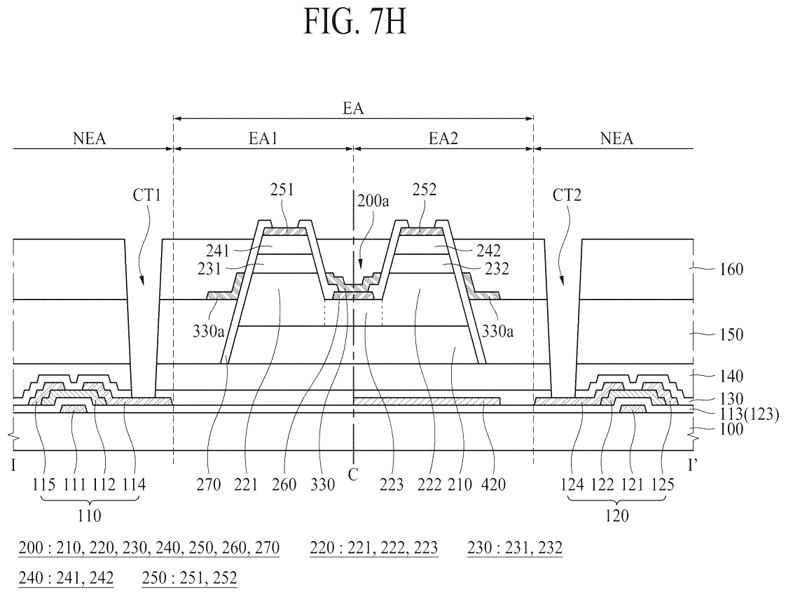

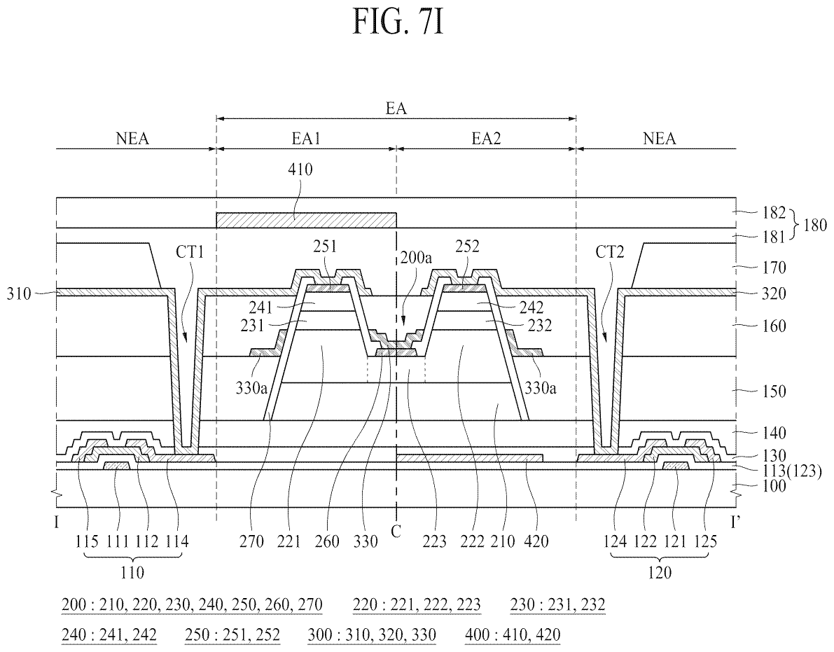

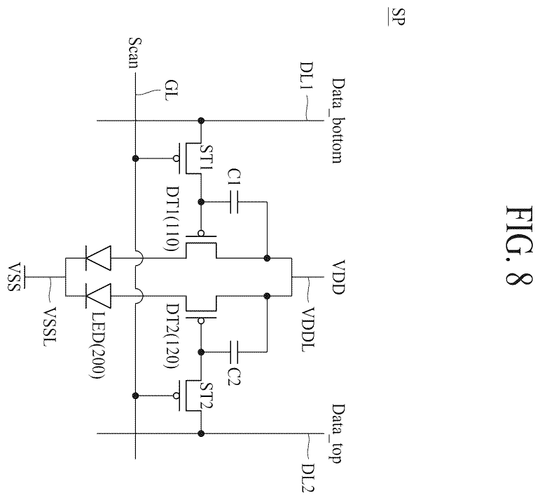

FIGS. 7A to 71 are cross-sectional views of steps in a manufacturing process of a display device according to one or more embodiments of the present disclosure. Also, FIGS. 7A to 71 are cross-sectional views taken along line I-I′ in FIG. 3 and thus may represent a manufacturing process of the sub-pixel SP of the display device 10.

Referring to FIG. 7A, a first thin film transistor 110, a second thin film transistor 120, a second reflective layer 420, an interlayer insulating layer 130, a passivation layer 140, and a light emitting diode 200 may be sequentially disposed on the substrate 100.

The first thin film transistor 110 may be disposed in the non-emitting area NEA adjacent to the first emitting area EA1, and the second thin film transistor 120 may be disposed in the non-emitting area NEA adjacent to the second emitting area EA2. The second reflective layer 420 may be disposed in the second light emitting area EA2. The second reflective layer 420 may be formed by the same process as the source electrodes 114 and the drain electrodes 115 of the first thin film transistors 110 and the source electrodes 124 and the drain electrodes 125 of the second thin film transistors 120, and may be formed of the same material, but is not limited thereto.

The interlayer insulating layer 130 and the passivation layer 140 may cover the first thin film transistor 110, the second thin film transistor 120, and the second reflective layer 420. Also, the light emitting diode 200 may be disposed in boundary regions of the first and second emitting areas EA1 and EA2.

Referring to FIG. 7B, the first planarization layer 150 may be disposed on the passivation layer 140. After a planarization material is deposited on the entire surface of the substrate 100, the partial region of the deposited planarization material may be removed to form the first and second contact holes CT1 and CT2. In this case, since the first planarization layer 150 surrounds a side surface of the light emitting diode 200, the light emitting diode 200 may be stably fixed on the passivation layer 140.

The distance from the substrate 100 to the upper surface of the first planarization layer 150 may be smaller than the distance from the substrate 100 to the upper surface of the n-type electrode 260. That is, the position of the upper surface of the first planarization layer 150 may be lower than the position of the upper surface of the n-type electrode 260. Accordingly, the upper surface of the n-type electrode 260 may be exposed by the first planarization layer 150.

Referring to FIG. 7C with continuing reference to FIG. 7B, a conductive material 330a may be deposited on the entire surface of the substrate 100. The conductive material 330a may be deposited to cover the first planarization layer 150, the inside of the first contact hole CT1, the inside of the second contact hole CT2, and the light emitting diode 200. The conductive material 330a may include a transparent conductive material, such as an indium tin oxide (ITO) or an indium zinc oxide (IZO).

Referring to FIG. 7D, a photoresist PR or photoresist layer PR may be formed on the conductive material 330a. The photoresist PR may cover the light emitting diode 200 and portions of the conductive material 330a surrounding the light emitting diode 200. Also, the photoresist PR may not cover the first and second contact holes CT1 and CT2. That is, one end (i.e., a left end) of the photoresist PR may be disposed between one side (i.e., a left side) of the light emitting diode 200 and the first contact hole CT1. Also, the other end (i.e., a right end) of the photoresist PR may be disposed between the other side (i.e., a right side) of the light emitting diode 200 and the second contact hole CT2 with the photoresist PR depositing and extending over the light emitting diode 200 between these termination points.

Referring to FIG. 7E, a thickness of the photoresist PR may be reduced through an ashing process. The thickness of the photoresist PR may be reduced to a thickness covering the conductive material 330a disposed on the n-type electrode 260. Also, the thickness of the photoresist PR may be reduced to a thickness that does not cover a plurality of active layers 230, a plurality of p-type semiconductor layers 240, and a plurality of p-type electrodes 250 meaning that these layers 230, 240, 250 are exposed following the ashing process, while the photoresist PR continues to cover the n-type electrode 260. That is, an upper surface of the photoresist PR may be disposed between an upper surface of the conductive material 330a disposed on the n-type electrode 260 and a lower surface of a plurality of active layers 230. In an embodiment, the upper or top surface of the photoresist PR after the ashing process is approximately aligned with the lower or bottom surface of the active layers 230 and the photoresist PR extends down to contact the conductive material 330a. Thus, the thickness of the photoresist PR after ashing is from the top surface of the conductive material 330a on the first planarization layer to the bottom surface of the active layers 230.

Referring to FIG. 7F, a portion of the conductive material 330a may be removed by an etching process, and a third connection electrode 330 may be formed from the remaining conductive material 330a. A partial area of the conductive material 330a exposed by the photoresist PR may be removed. Specifically, the region of conductive material 330a overlapping the first and second contact holes CT1 and CT2 and the region of conductive material 330a overlapping the first and second p-type electrodes 251 and 252 may be removed and only the portion of the conductive material 330a covered by the photoresist PR may remain. Accordingly, a portion of the conductive material 330a adjacent to one side (i.e., a left side) and the other side (i.e., a right side) of the light emitting diode 200 may remain on the first planarization layer 150. Also, the conductive material 330a formed on the n-type electrode 260 may remain. In this case, the conductive material 330a formed on the n-type electrode 260 may function as the third connection electrode 330. The remaining portion of the conductive material 330a may be disposed on a portion of a top surface of the first planarization layer, a lower portion of a side surface of the protective layer 270 (i.e., a lower portion of a side surface of the light emitting diode 200), and on the n-type electrode 260.

Referring to FIG. 7G, the remaining photoresist PR may be completely removed to expose the remaining conductive material 330a and form the completed and exposed third connection electrode 330. Accordingly, the third connection electrode 330 may be formed on the n-type electrode 260.

That is, the present disclose contemplates forming the third connection electrode 330 by depositing the conductive material 330a on the entire surface of the substrate 100 and then removing part, or in some examples, most of the conductive material 330a using the photoresist PR. In this case, in the process of depositing the conductive material 330a on the entire surface of the substrate 100, the n-type electrode 260 of the light emitting diode 200 and the conductive material 330a may necessarily come in contact with each other. Also, even if an error occurs in the arrangement position of the photoresist PR, since the n-type electrode 260 is located at the center of the light emitting diode 200, the possibility that the conductive material 330a on the n-type electrode 260 will be removed may be remarkably low. Accordingly, the third connection electrode 330 may be stably connected to the n-type electrode 260.

Also, referring to FIG. 7G, the remaining or unremoved portion of the conductive material 330a may remain on one side (left side) and the other side (right side) of the light emitting diode 200, as described above. The remaining conductive material 330a may include the same material as the third connection electrode 330. Also, the remaining conductive material 330a may be present on the first planarization layer 150, and may be present on the side surface of the light emitting diode 200 in contact with the protective layer 270 of the light emitting diode 200. However, the n-type electrode 260 may be electrically separated from the remaining conductive material 330a by the groove 200a of the light emitting diode 200. Thus, the process for removing the remaining conductive material 330a may be omitted.

Referring to FIG. 7H, the second planarization layer 160 may be disposed on the first planarization layer 150. After the planarization material is deposited on the entire surface of the substrate 100, a portion of the planarization material may be removed to make the first and second contact holes CT1 and CT2. In an embodiment, depositing the second planarization layer 160 includes filling the first and second contact holes CT1 and CT2 described with reference to FIGS. 7B-7G. After the second planarization layer 160 is deposited, portions of the second planarization layer 160 can be removed to form the contact holes CT1, CT2 illustrated in FIG. 7H. Thereafter, a photoresist process may be performed to remove a portion of of the interlayer insulating layer 130 and a portion of the passivation layer 140 overlapping the first and second contact holes CT1 and CT2 to complete the contact holes CT1, CT2. Accordingly, the first and second contact holes CT1 and CT2 may expose the source electrodes 114 of the first thin film transistor 110 and the source electrodes 124 of the second thin film transistor 120.

Referring to FIG. 7I, the first and second connection electrodes 310 and 320, the bank 170, the first encapsulation layer 181, the first reflective layer 410, and the second encapsulation layer 182 may be sequentially formed.

After depositing a conductive material on the entire surface of the substrate 100, a portion of the deposited conductive material may be removed to form the first and second connection electrodes 310 and 320. A region of the deposited conductive material overlapping the n-type electrode 260 may be removed. Accordingly, the first connection electrode 310 may be formed on the second planarization layer 160 and may be formed in the first emitting area EA1 and the non-emitting area NEA. Furthermore, the second connection electrode 320 may be formed on the second planarization layer 160 and may be formed in the second emitting area EA2 and the non-emitting area NEA. Furthermore, the first and second connection electrodes 310 and 320 may be spaced apart from each other.

After depositing an inorganic insulating material on the entire surface of the substrate 100, a bank 170 may be formed by removing a partial of deposited inorganic insulating material. Specifically, a region of deposited inorganic insulating material overlapping the emitting area EA may be removed. Also, the first encapsulation layer 181 may be formed on the entire surface of the substrate 100. The first encapsulation layer 181 may fill the inside of the first contact hole CT1 and the inside of second contact hole CT2.

The first reflective layer 410 may be formed on the first encapsulation layer 181. The first reflective layer 410 may be formed in the first emitting area EA1 and may not be formed in the second emitting area EA2. Furthermore, the first reflective layer 410 may overlap the first protrusion 221 of the n-type semiconductor layer 220. Furthermore, the second encapsulation layer 182 may be formed on the first reflective layer 410 and may compensate for a step difference caused by the first reflective layer 410.

FIG. 8 is a circuit diagram of a sub-pixel SP of the display device 10 according to an embodiment of the present disclosure.

Referring to FIG. 8, the sub-pixel SP may include first and second storage capacitors C1 and C2, first and second switching transistors ST1 and ST2, first and second driving transistors DT1 and DT2, and one light emitting diode LED.

Each of the first and second switching transistors ST1 and ST2 and the first and second driving transistors DT1 and DT2 of each sub-pixel SP includes a gate electrode, a source electrode, and a drain electrode. Since the source electrode and the drain electrode are not fixed and may be changed according to voltage and current directions applied to the gate electrode, any one of the source electrode and the drain electrode may be represented as the first electrode, and the other may be represented as the second electrode.

The light emitting diode LED may include a first anode electrode connected to the first driving transistor DT1, a second anode electrode connected to the second driving transistor DT2, and a cathode electrode applied a second power voltage VSS from the second power line VSSL.

The first anode electrode may receive a driving current from the first driving transistor DT1, and the second anode electrode may receive a driving current from the second driving transistor DT2. That is, the light emitting diode LED of the present disclosure discloses the first and second anode electrodes that are independently formed, and the first and second anode electrodes may receive the driving current from different driving transistors.

The first anode electrode, the second anode electrode, and the cathode electrode of the light emitting diode LED of FIG. 8 may correspond to the first p-type electrode 251, the second p-type electrode 252, and the n-type electrode 260 of the light emitting diode 200 described above in FIG. 4. In addition, the light emitting diode (LED) of the present disclosure may be a micro LED having a small size for high quality image and may be have a lateral structure.

The first electrode of the first driving transistor DT1 may be connected to the first power line VDDL supplying the first power voltage VDD, and the second electrode may be connected to the first anode electrode of the light emitting diode LED. In addition, the first electrode of the second driving transistor DT2 may be connected to the first power line VDDL supplying the first power voltage VDD, and the second electrode may be connected to the second anode electrode of the light emitting diode LED. The first and second driving transistors DT1 and DT2 of FIG. 8 may correspond to the first and second thin film transistors 110 and 120 described in FIG. 4.

The first storage capacitor C1 may be connected between the gate electrode and the second electrode of the first driving transistor DT1 to charge the driving voltage corresponding to the first data voltage Data_bottom. In the non-emission period, the first storage capacitor C1 may maintain the charged driving voltage and supply the maintained driving voltage to the first driving transistor DT1. In addition, the second storage capacitor C2 may be connected between the gate electrode and the second electrode of the second driving transistor DT2 to charge the driving voltage corresponding to the second data voltage Data_top. In the non-emission period, the second storage capacitor C2 may maintain the charged driving voltage and supply the maintained driving voltage to the second driving transistor DT2. That is, each of the first and second storage capacitors C1 and C2 may charge a driving voltage corresponding to different data voltages.

The first and second switching transistors ST1 and ST2 may drive depending on the scan signal Scan supplied through the gate line GL. The first switching transistor ST1 may supply the first data voltage Data_bottom supplied through the first data line DL1 to the first electrode of the first storage capacitor C1. In addition, the second switching transistor ST2 may supply the second data voltage Data_top supplied through the second data line DL2 to the first electrode of the second storage capacitor C2. That is, the first and second switching transistors ST1 and ST2 are driven through the same scan signal, but may supply data voltages to different storage capacitors.

In conclusion, the light emitting diode (LED) of the present disclosure includes first and second anode electrodes that are independently formed, and discloses driving the first and second anode electrodes with the first and second driving transistors, respectively. Accordingly, even if a plurality of light emitting diodes are not formed in one sub-pixel, it may be disclosed that one sub-pixel has two independent emitting areas from a common single light emitting diode. Therefore, the circuit structure of the sub-pixel may be simplified.

According to the present disclosure, the following advantageous effects may be obtained, among others.

According to the present disclosure, the plurality of light conversion layers may be formed so that light efficiency may be improved, and reflectance due to external light may be reduced. In addition, the disclosure provides for a dual-emitting type display (i.e., emits lights in two opposite directions) that overcomes the disadvantages of known displays described above.

One or more embodiments of a display device may include: a substrate; a plurality of sub-pixels disposed on the substrate, each of the plurality of sub-pixels including an emitting area and a non-emitting area surrounding the emitting area; a first thin film transistor disposed on the substrate in the non-emitting area; a second thin film transistor disposed on the substrate in the non-emitting area; and a light emitting diode disposed on the substrate in the emitting area, the light emitting diode including a first p-type electrode and a second p-type electrode, wherein the first p-type electrode is electrically connected to the first thin film transistor and the second p-type electrode is electrically connected to the second thin film transistor.

In an embodiment, the light emitting diode further includes: a buffer layer disposed on the substrate; an n-type semiconductor layer disposed on the buffer layer; a first active layer, a second active layer, and an n-type electrode disposed on the n-type semiconductor layer; a first p-type semiconductor layer disposed on the first active layer; and a second p-type semiconductor layer disposed on the second active layer.

In an embodiment, the n-type semiconductor layer includes: a first protrusion portion disposed on a first side of the n-type semiconductor layer; a second protrusion portion disposed on a second, opposite side of the n-type semiconductor layer; a concave portion disposed between the first protrusion portion and the second protrusion portion; and a groove between the first protrusion portion and the second protrusion portion, the groove corresponding to the concave portion.

In an embodiment, the emitting area includes a first emitting area and a second emitting area, the first protrusion portion of the n-type semiconductor layer is disposed in the first emitting area, the second protrusion portion of the n-type semiconductor layer is disposed in the second emitting area, and the concave portion of the n-type semiconductor layer is disposed at a boundary between the first emitting area and the second emitting area.

In an embodiment, the first active layer, the first p-type semiconductor layer, and the first p-type electrode are sequentially disposed on the first protrusion portion of the n-type semiconductor layer, the second active layer, the second p-type semiconductor layer, and the second p-type electrode are sequentially disposed on the second protrusion portion of the n-type semiconductor layer, and the n-type electrode is disposed on the concave portion of the n-type semiconductor layer.

In an embodiment, the first active layer and the second active layer are spaced apart from each other, and the first p-type semiconductor layer and the second p-type semiconductor layer are spaced apart from each other.

In an embodiment, the display device further includes: a first reflective layer disposed on the first protrusion portion; and a second reflective layer disposed on the substrate and overlapping the second protrusion portion.

In an embodiment, the display device further includes: a first reflective member disposed on an upper surface of the first p-type electrode; and a second reflective member disposed on a lower surface of the buffer layer and overlapping the second protrusion portion.

In an embodiment, the display device further includes: a first connection electrode, a second connection electrode, and a third connection electrode each disposed on the substrate; and a common voltage line, wherein the first connection electrode electrically connects the first thin film transistor with the first p-type electrode, the second connection electrode electrically connects the second thin film transistor with the second p-type electrode, and the third connection electrode electrically connects the common voltage line with the n-type electrode.

In an embodiment, the display device further includes: a first planarization layer disposed on the substrate and surrounding a side surface of the light emitting diode; and a second planarization layer disposed on the first planarization layer and covering an upper surface of the light emitting diode.

In an embodiment, the first connection electrode and the second connection electrode are disposed on the second planarization layer, and the third connection electrode is disposed between the first planarization layer and the second planarization layer.

In an embodiment, the third connection electrode is disposed in the groove of the light emitting diode.

In an embodiment, the display device further includes: a conductive material disposed between the first planarization layer and the second planarization layer, wherein the conductive material is made of the same material as the third connection electrode, and wherein the conductive material is disposed on the side surface of the light emitting diode.

One or more embodiments of a display device may include: a substrate; a plurality of sub-pixels disposed on the substrate, each of the plurality of sub-pixels including an emitting area and a non-emitting area surrounding the emitting area; and a light emitting diode disposed on the substrate in the emitting area, the light emitting diode including a buffer layer disposed on the substrate, a first p-type electrode disposed on a first side of the buffer layer, a second p-type electrode disposed on a second side of the buffer layer, and an n-type electrode disposed on a center of the buffer layer, wherein the first p-type electrode and the n-type electrode are spaced apart from each other, and the second p-type electrode and the n-type electrode are spaced apart from each other.

In an embodiment, the display device further includes: a first connection electrode, a second connection electrode, and a third connection electrode each disposed on the light emitting diode, wherein the first connection electrode overlaps the first p-type electrode, the second connection electrode overlaps the second p-type electrode, the third connection electrode overlaps the n-type electrode, and the first connection electrode, the second connection electrode, and the third connection electrode are spaced apart from each other.

In an embodiment, the first connection electrode is configured to receive a first voltage through a first contact hole, the second connection electrode is configured to receive a second voltage through a second contact hole, the third connection electrode is configured to receive a third voltage through a third contact hole, and the first contact hole, the second contact hole, and the third contact hole are disposed in the non-emitting area.

In an embodiment, the plurality of sub-pixels include a first sub-pixel, a second sub-pixel, and a third sub-pixel, the first connection electrode is independently disposed in each of the first sub-pixel, the second sub-pixel, and the third sub-pixel, the second connection electrode is independently disposed in each of the first sub-pixel, the second sub-pixel, and the third sub-pixel, and the third connection electrode is disposed in all of the first sub-pixel, the second sub-pixel, and the third sub-pixel.

One or more embodiments of a display device may include a plurality of sub-pixels, wherein each of the plurality of sub-pixels includes: a light emitting diode having a first anode electrode, a second anode electrode, and a cathode electrode; a first driving transistor including a first electrode connected to the first anode electrode; a second driving transistor including a first electrode connected to the second anode electrode.

In an embodiment, the first driving transistor includes a gate electrode and a second electrode, the second driving transistor includes a gate electrode and a second electrode, each of the plurality of sub-pixels includes a first storage capacitor connected between the gate electrode of the first driving transistor and the second electrode of the first driving transistor, and each of the plurality of sub-pixels includes a second storage capacitor connected between the gate electrode of the second driving transistor and the second electrode of the second driving transistor.

In an embodiment, each of the plurality of sub-pixels includes a first switching transistor configured to supply a first data voltage from a first data line to an electrode of the first storage capacitor, and each of the plurality of sub-pixels includes a second switching transistor configured to supply a second data voltage from a second data line to an electrode of the second storage capacitor.

It will be apparent to those skilled in the art that the present disclosure described above is not limited by the above-described embodiments and the accompanying drawings and that various substitutions, modifications and variations can be made in the present disclosure without departing from the spirit or scope of the disclosures. The scope of the claims is not defined or limited by the disclosure and it is intended that all variations or modifications derived from the meaning, scope and equivalent concept of the claims fall within the scope of the claims.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate;
a plurality of sub-pixels disposed on the substrate, each of the plurality of sub-pixels including an emitting area and a non-emitting area surrounding the emitting area;
a first thin film transistor disposed on the substrate in the non-emitting area;
a second thin film transistor disposed on the substrate in the non-emitting area; and
a light emitting diode disposed on the substrate in the emitting area, the light emitting diode including a first p-type electrode and a second p-type electrode,
wherein the first p-type electrode is electrically connected to the first thin film transistor and the second p-type electrode is electrically connected to the second thin film transistor.

2. The display device of claim 1, wherein the light emitting diode further includes:
a buffer layer disposed on the substrate;
an n-type semiconductor layer disposed on the buffer layer;
a first active layer, a second active layer, and an n-type electrode disposed on the n-type semiconductor layer;
a first p-type semiconductor layer disposed on the first active layer; and
a second p-type semiconductor layer disposed on the second active layer.

3. The display device of claim 2, wherein the n-type semiconductor layer includes:
a first protrusion portion disposed on a first side of the n-type semiconductor layer;
a second protrusion portion disposed on a second, opposite side of the n-type semiconductor layer;
a concave portion disposed between the first protrusion portion and the second protrusion portion; and
a groove between the first protrusion portion and the second protrusion portion, the groove corresponding to the concave portion.

4. The display device of claim 3, wherein the emitting area includes a first emitting area and a second emitting area,
the first protrusion portion of the n-type semiconductor layer is disposed in the first emitting area,
the second protrusion portion of the n-type semiconductor layer is disposed in the second emitting area, and
the concave portion of the n-type semiconductor layer is disposed at a boundary between the first emitting area and the second emitting area.

5. The display device of claim 4, wherein the first active layer, the first p-type semiconductor layer, and the first p-type electrode are sequentially disposed on the first protrusion portion of the n-type semiconductor layer,
the second active layer, the second p-type semiconductor layer, and the second p-type electrode are sequentially disposed on the second protrusion portion of the n-type semiconductor layer, and
the n-type electrode is disposed on the concave portion of the n-type semiconductor layer.

6. The display device of claim 5, wherein the first active layer and the second active layer are spaced apart from each other, and
the first p-type semiconductor layer and the second p-type semiconductor layer are spaced apart from each other.

7. The display device of claim 4, further comprising:
a first reflective layer disposed on the first protrusion portion; and
a second reflective layer disposed on the substrate and overlapping the second protrusion portion.

8. The display device of claim 4, further comprising:
a first reflective member disposed on an upper surface of the first p-type electrode; and
a second reflective member disposed on a lower surface of the buffer layer and overlapping the second protrusion portion.

9. The display device of claim 3, further comprising:
a first connection electrode, a second connection electrode, and a third connection electrode each disposed on the substrate; and
a common voltage line,
wherein the first connection electrode electrically connects the first thin film transistor with the first p-type electrode,
the second connection electrode electrically connects the second thin film transistor with the second p-type electrode, and
the third connection electrode electrically connects the common voltage line with the n-type electrode.

10. The display device of claim 9, further comprising:
a first planarization layer disposed on the substrate and surrounding a side surface of the light emitting diode; and
a second planarization layer disposed on the first planarization layer and covering an upper surface of the light emitting diode.

11. The display device of claim 10, wherein the first connection electrode and the second connection electrode are disposed on the second planarization layer, and
the third connection electrode is disposed between the first planarization layer and the second planarization layer.

12. The display device of claim 11, wherein the third connection electrode is disposed in the groove of the light emitting diode.

13. The display device of claim 10, further comprising:
a conductive material disposed between the first planarization layer and the second planarization layer,
wherein the conductive material is made of the same material as the third connection electrode, and
wherein the conductive material is disposed on the side surface of the light emitting diode.

14. A display device, comprising:
a substrate;
a plurality of sub-pixels disposed on the substrate, each of the plurality of sub-pixels including an emitting area and a non-emitting area surrounding the emitting area; and
a light emitting diode disposed on the substrate in the emitting area, the light emitting diode including:
a buffer layer disposed on the substrate;
a first p-type electrode disposed on a first side of the buffer layer;
a second p-type electrode disposed on a second side of the buffer layer; and
an n-type electrode disposed on a center of the buffer layer,
wherein the first p-type electrode and the n-type electrode are spaced apart from each other, and
the second p-type electrode and the n-type electrode are spaced apart from each other.

15. The display device of claim 14, further comprising:
a first connection electrode, a second connection electrode, and a third connection electrode each disposed on the light emitting diode,
wherein the first connection electrode overlaps the first p-type electrode,
the second connection electrode overlaps the second p-type electrode,
the third connection electrode overlaps the n-type electrode, and
the first connection electrode, the second connection electrode, and the third connection electrode are spaced apart from each other.

16. The display device of claim 15, wherein the first connection electrode is configured to receive a first voltage through a first contact hole,
the second connection electrode is configured to receive a second voltage through a second contact hole,
the third connection electrode is configured to receive a third voltage through a third contact hole, and
the first contact hole, the second contact hole, and the third contact hole are disposed in the non-emitting area.

17. The display device of claim 15, wherein the plurality of sub-pixels include a first sub-pixel, a second sub-pixel, and a third sub-pixel,
the first connection electrode is independently disposed in each of the first sub-pixel, the second sub-pixel, and the third sub-pixel,
the second connection electrode is independently disposed in each of the first sub-pixel, the second sub-pixel, and the third sub-pixel, and
the third connection electrode is disposed in all of the first sub-pixel, the second sub-pixel, and the third sub-pixel.

18. A display device, comprising:
a plurality of sub-pixels, wherein each of the plurality of sub-pixels includes:
a light emitting diode having a first anode electrode, a second anode electrode, and a cathode electrode;
a first driving transistor including a first electrode connected to the first anode electrode; and
a second driving transistor including a first electrode connected to the second anode electrode.

19. The display device of claim 18, wherein the first driving transistor includes a gate electrode and a second electrode,
the second driving transistor includes a gate electrode and a second electrode,
each of the plurality of sub-pixels includes a first storage capacitor connected between the gate electrode of the first driving transistor and the second electrode of the first driving transistor, and
each of the plurality of sub-pixels includes a second storage capacitor connected between the gate electrode of the second driving transistor and the second electrode of the second driving transistor.

20. The display device of claim 18, wherein each of the plurality of sub-pixels includes a first switching transistor configured to supply a first data voltage from a first data line to an electrode of the first storage capacitor, and
each of the plurality of sub-pixels includes a second switching transistor configured to supply a second data voltage from a second data line to an electrode of the second storage capacitor.
